(19) United States
(12) Patent Application Publication
(10) Pub. No.: US 2004/0179402 A1
(43) Pub. Date: Sep. 16, 2004

(54) Method of physical page allocation for flash memory

(76) Inventor: Ling-Chien Chen, Taipei (TW)

Correspondence Address: ANTHONY R BARKUME, 20 GATEWAY LANE, MANORVILLE, NY, 11949, US

(21) Appl. No.: 10/757,013

(22) Filed: Jan. 14, 2004

(30) Foreign Application Priority Data
Mar. 12, 2003 (TW) 92105403

(51) Int. Cl. G11C 11/34; G11C 16/04

(52) U.S. Cl. 365/185.12

(57) ABSTRACT

The present invention is related to a method of physical page allocation for speeding up the access speed of flash memory with multiple memory chips. There are steps of: defining N sequential pages as a page set, wherein N is a positive number; allocating a first page set into a first memory chip; allocating a second page set into a second memory chip, wherein the second page set is next to the first page set; allocating a third page set into the first memory chip; allocating a forth page set into the second memory chip, where in the forth page set is next to the third page set.

### FIELD OF THE INVENTION

The present invention is related to a method of physical page allocation flash memory, particularly to a method for speeding up the access speed of flash memory.

### BACKGROUND OF THE INVENTION

Flash memory is a non-volatilized memory. As well as the EEPROM (electrical erasable and programmable read only Memory), the data may be erased by electronic method and modified for thousands to millions times sequentially. And, the data will be saved for almost ten years without lost after power off. What the flash memory is different from EEPROM is that flash memory has a lower cost, a higher speed and higher bit density. So, the flash memory has being taken place with EEPROM gradually and becomes the most potential technique in the non-volatilized memory.

Please refer to FIG. 1. The physical page allocation of conventional flash memory uses a cascade mode and starts from memory chip CS0 to allocate pages from Page-0 to Page-m. The memory chip CS1 follows the memory chip CS0 and allocates pages from Page-m+1. Accordingly, the allocation doesn't complete until the memory chip CS3 allocates to the last page Page-n.

FIG. 2 shows the access timing flow chart of the conventional flash memory. Due to the physical page allocation of the conventional flash memory uses a cascade mode, the data write-in procedure is one by one. That is, the second data doesn't write-in until the first data is written completely. This is why the access speed of the conventional flash memory cannot be improved. Due to the fast development of semiconductor process, the capacity of flash memory upgrades very quickly. Therefore, to speed up the access time is a big issue.

### SUMMARY OF THE INVENTION

An objective of the present invention is to provide a physical page allocation method for speeding up the access of flash memory.

Another objective of the present invention is to provide a physical page allocation method for allocating the first page or first page set into the first memory chip, and the second or second page set into the second chip. So that, when a huge amount and sequential data is written, the second memory chip can process the writing-in procedure for the second page data without waiting for the data writing of the first memory chip.

### BRIEF DESCRIPTION OF THE INVENTION

According to the present invention, a method for a physical page allocation of multiple memory chips comprises steps of: defining N sequential pages as a page set, wherein N is a positive integer; allocating a first page set into a first memory chip; allocating a second page set into a second memory chip, wherein the second page set is sequentially next to the first page set; allocating a third page set into the first memory chip; and allocating a fourth page set into the second memory chip, wherein the fourth page set is sequentially next to the third page set.

In accordance with one aspect of the present invention, the memory is a flash memory.

In accordance with one aspect of the present invention, the memory size of each page is 512 Bytes.

In accordance with one aspect of the present invention, the memory size of each page set is 512*N Bytes.

In accordance with one aspect of the present invention, according to the third page next to the second page set, the allocation method is a 2-way interleave mode.

According to the present invention, a method for physical allocation for multiple memory chips comprises steps of:

Defining N sequential pages-as a page set, wherein N is a positive integer;

Allocating a first page set into a first memory chip;

Allocating a second page set into a second memory chip, wherein the second page set is sequentially next to the first page set;

Allocating a third page set into a third memory chip;

Allocating a fourth page set into a fourth memory chip, wherein the fourth page set is sequentially next to the third page set.

Allocating a fifth page set into the first memory chip;

Allocating a sixth page set into the second memory chip, wherein the sixth page set is sequentially next to the fifth page set.

Allocating a seventh page set into the third memory chip; and

Allocating a eighth page set into the fourth memory chip, wherein the eighth page set is sequentially next to the seventh page set.

In accordance with one aspect of the present invention, the memory is a flash memory.

In accordance with one aspect of the present invention, the memory size of each page is 512 Bytes.

In accordance with one aspect of the present invention, the memory size of each page set is 512*N Bytes.

In accordance with one aspect of the present invention, according to the fifth page next to the second page set and the seventh page set next to the fourth page sets, the allocation method is a 2-way interleave mode.

In accordance with one aspect of the present invention, according to the third page set next to the second page set, the seventh page set next to the sixth page set and the fifth page set next to the fourth page set, the allocation method is a 4-way interleave mode.

The present invention may best be understood through the following description with reference to the accompanying drawings, wherein:

### BRIEF DESCRIPTION OF THE DRAWINGS

FIG. 1 shows a conventional physical page allocation method of flash memory;

FIG. 2 shows the access clock diagram of the conventional flash memory;

FIG. 3 shows a physical page allocation method of memory according to the present invention;

FIG. 4 shows an access clock diagram according to the present invention;

FIG. 5 shows a physical page allocation method of memory by 4-way interleave mode solution;

FIG. 6 shows a physical page allocation of memory wherein the memory size of each page is 1024 Bytes; and

FIG. 7 shows a physical page allocation of memory wherein the memory size of each page is 2048 Bytes.

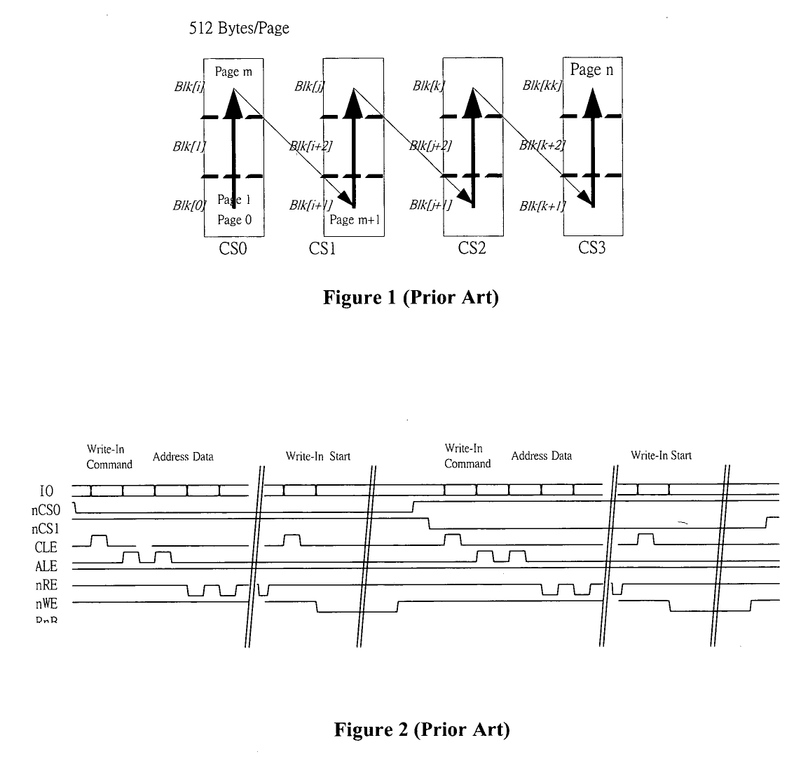

### DETAILED DESCRIPTION OF THE PREFERRED EMBODIMENT

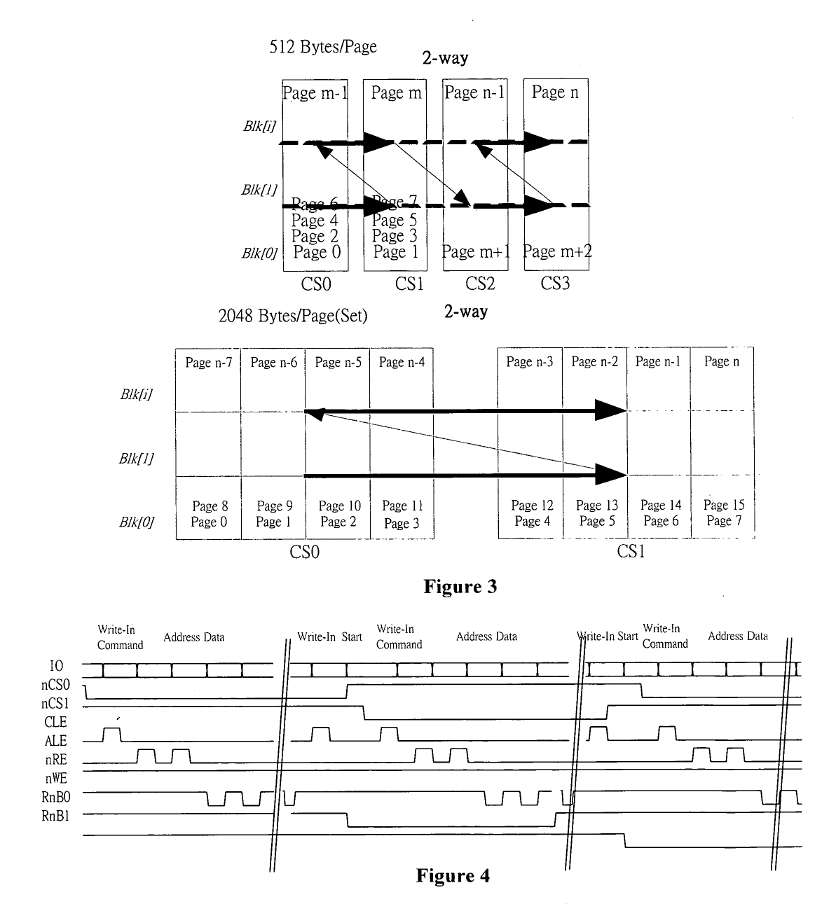

Please refer FIG. 3. In the upper diagram of FIG. 3, there is a page set having a page, and the memory size of each page is 512 Bytes. In the lower diagram of FIG. 3, each page set contains 4 pages, and the memory size is 2048 Bytes. The detail description of the upper diagram of FIG. 3 is introduced as follows.

Please refer the upper diagram of FIG. 3. This is an example of 2-way interleave mode of physical page allocation method according to the present invention. We firstly interleave the memory chip CS0 (the first memory chip) and CS1 (the second memory chip) for page allocation, that is, allocating Page 0 (the first page set, there is only one page in the page set when N=1) into CS0, allocating Page 1 (the second page set, there is only one page in the page set when N=1) into CS1, and then allocating Page 2 (the third page set, there is only one page in the page set when N=1) into CS0, allocating Page 3 (the fourth page set, there is only one page in the page set when N=1) into CS1, etc., until allocating Page m−1 into CS0 and Page m into CS1. After allocating the memory size of memory chip CS0 and CS1, we keep on interleave the other pages and allocating them into memory chip CS2 and CS3, that is, allocating Page m+3 into CS2, allocating Page m+4 into CS3, etc., until allocating Page n−1 into CS2 and Page n into CS3.

FIG. 4 shows the access clock diagram according to the present invention. Due to the usage of interleave mode in the physical page allocation, each page and its neighbored pages all are allocated in the different memory chips, so whenever the actual write-in procedure begins to process after the program command starting (at this moment the busy signal RnB0 will be changed from high voltage level to low voltage level). The memory cell will be able to process the write-in procedure of the next data without waiting for the actual write-in activity completes, especially for writing huge and sequential data into the memory. Therefore, this physical page allocation with 2-way interleave mode is able to improve the access speed for at least 2 times than the conventional technique.

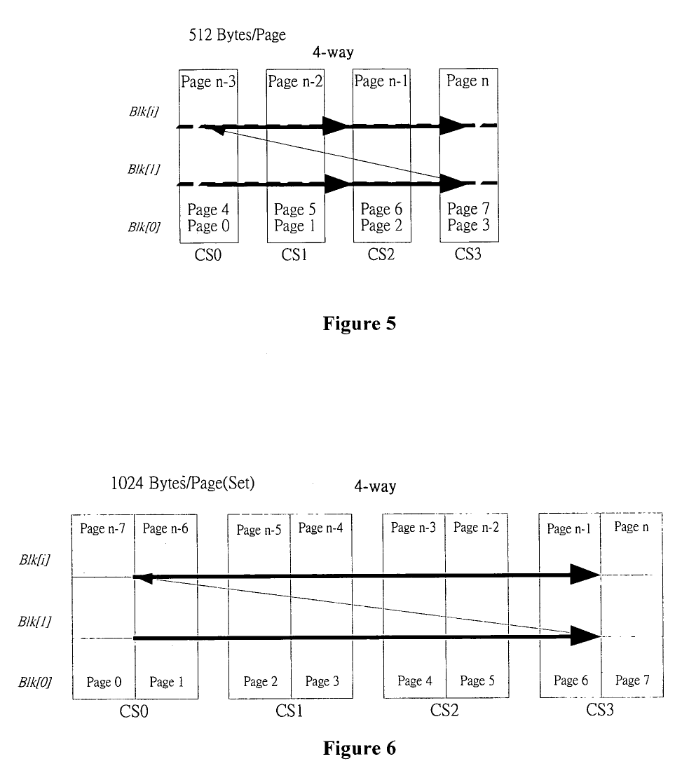

FIG. 5 is another preferred embodiment according to the present invention. 4-way interleave mode is adopted in the physical page allocation solution. The memory size of each page is 512 Bytes. In this figure, each of pages are interleaved and allocated into memory chip CS0 (the first memory chip) [symbol] CS1 (the second memory chip) [symbol] CS2 (the third memory chip) and CS3 (the fourth memory chip). That is, Page 0 (the first page set, there is only one page in this page set when N=1), Page 1 (the second page set, there is only one page in this page set when N=1), Page 2 (the fifth page set, there is only one page in this page set when N=1) and Page 3 (the sixth page set, there is only one page in this page set when N=1) are allocated into CS0 [symbol] CS1 [symbol] CS2 and CS3 respectively. And, then Page 4 (the third page set, there is only one page in this page set when N=1), Page 5 (the fourth page set, there is only one page in this page set when N=1), Page 6 and Page 7 will be allocated into CS0 [symbol] CS1 [symbol] CS2 and CS3 respectively, etc. Finally, Page n−3 [symbol] Page n−2 [symbol] Page n−1 and Page n are allocated into CS0, CS1, CS2, and CS3. The access clock diagram of this physical page allocation by 4-way interleave mode is also shown as FIG. 4. So, whenever the actual write-in procedure of data begins to process after program command starting (at this moment the busy signal RnB0 will be changed from high voltage level to low voltage level), the memory cell will be able to process the write-in procedure of next data without waiting for the actual write-in activity completes, especially for writing huge and sequential data into the memory. Therefore, this physical page allocation with 4-way interleave mode is able to improve the access speed for at least 4 times than the conventional technique.

FIG. 6 is another preferred embodiment according to the present invention, wherein each of two 512 Bytes pages is merged as a page set (N=2), so the memory size of each page set is 1024 Bytes. And the physical page allocation of memory is able to use 4-way interleave mode or 2-way interleave mode. In this figure, each page set will be interleaved and allocated into memory chip CS0, CS1, CS2 and CS3. That is, Page 0/Page 1, Page 2/Page 3, Page 4/Page 5, Page 6/Page 7 are allocated into CS0, CS1, CS2, and CS3 respectively. And, then Page 8/Page 9, Page 10/Page 11, Page 12/ Page 13, and Page 14/Page 15 keep on allocating into CS0, CS1, CS2, and CS3, etc. Finally, Page n−7/ Page n−6, Page n−5/ Page n−4, Page n−3/Page n−2, and Page n−1/Page n are allocated into CS0, CS1, CS2, and CS3.

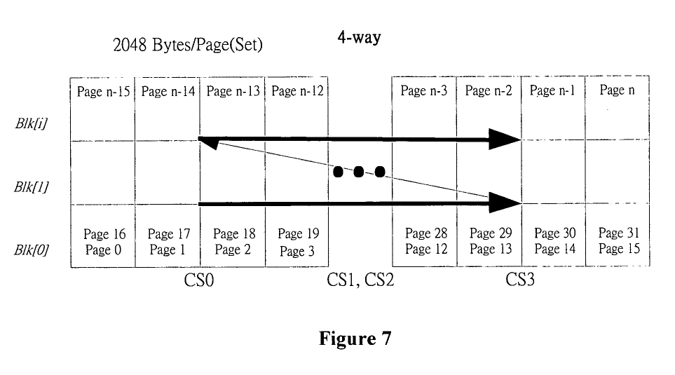

FIG. 7 is another preferred embodiment according to the present invention, wherein each of four 512 Bytes pages will be merged as a page set (N=4), so the memory size of each page set is 2048 Bytes, and the physical page allocation of memory is able to use 4-way interleave mode or 2-way interleave mode. In this figure, each page set will be interleaved and allocated into memory chip CS0, CS1, CS2 and CS3, that is, Page 0 to Page 3, Page 4 to Page 7, Page 8 to Page 11, Page 12 to Page 15 are allocated into CS0, CS1, CS2, and CS3 respectively. And, then Page 16 to Page 19, Page 20 to Page 23, Page 24 to Page 27, and Page 28 to Page 31 keep on allocating into CS0, CS1, CS2, and CS3, etc. Finally, Page n−15 to Page n−12, Page n−11 to Page n−8, Page n−7 to Page n−4, and Page n−3 to Page n are allocated into CS0, CS1, CS2, and CS3.

The access clock diagram of the examples in FIG. 6 and FIG. 7 can also be shown as FIG. 4 by the physical page allocation with 2-way interleave mode or 4-way interleave mode. And, the writing-in speed will be enhanced to at least 2 to 4 times than the conventional technique. Further more, if the flash memory size of each page set is larger than each single page, then they are able to be merged together into a read command for physical reading activity. Then the sequential read commands will not be re-executed next time to process the read activity directly, to achieve the high access target by saving the waiting time of components.

The present invention provides an improvement solution to the conventional technique, by allocating each page or page set of the memory and its neighbored pages or page sets into different memory chips, whenever the actual write-in procedure of each data begins to process after program command starting, the memory cell will be able to process the write-in procedure of the next data without waiting for the actual write-in activity completes, especially for writing huge and sequential data into the memory. Therefore, the present invention is able to speed up the access speed of memory. The enhancement of the present invention is, the access speed of memory, especially for flash memory, will be enhanced to at least 2 to 4 times than the conventional technique by 2-way interleave mode or 4-way interleave mode in the physical page allocation, and then we may achieve the objective of speed up the access speed of memory.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for a physical page allocation of multiple memory chips comprises steps of:
defining N sequential pages as a page set, wherein N is a positive integer;
allocating a first page set into a first memory chip;
allocating a second page set into a second memory chip, wherein the second page set is sequentially next to the first page set;
allocating a third page set into the first memory chip; and
allocating a fourth page set into the second memory chip, wherein the fourth page set is sequentially next to the third page set.

2. The method according to claim 1 wherein said memory is a flash memory.

3. The method according to claim 1 wherein said memory size of each page is 512 Bytes.

4. The method according to claim 1 wherein said memory size of each page set is 512*N Bytes.

5. The method according to claim 1 wherein said allocation method is a 2-way interleave mode according to said third page next to said second page set.

6. A method for physical allocation for multiple memory chips comprises steps of:
Defining N sequential pages as a page set, wherein N is a positive integer;
Allocating a first page set into a first memory chip;
Allocating a second page set into a second memory chip, wherein said second page set is sequentially next to said first page set;
Allocating a third page set into a third memory chip;
Allocating a fourth page set into a fourth memory chip, wherein the fourth page set is sequentially next to the third page set.
Allocating a fifth page set into the first memory chip;
Allocating a sixth page set into the second memory chip, wherein the sixth page set is sequentially next to the fifth page set.
Allocating a seventh page set into the third memory chip; and
Allocating a eighth page set into the fourth memory chip, wherein the eighth page set is sequentially next to the seventh page set.

7. The method according to claim 6 wherein said memory is a flash memory.

8. The method according to claim 6 wherein said memory size of each page is 512 Bytes.

9. The method according to claim 6 wherein said memory size of each page set is 512*N Bytes.

10. The method according to claim 6 wherein said allocation method is a 2-way interleave mode according to the fifth page next to the second page set and the seventh page set next to the fourth page sets.

11. The method according to claim 6 wherein said allocation method is a 4-way interleave mode according to the third page set next to the second page set, the seventh page set next to the sixth page set and the fifth page set next to the fourth page set.
